(19) United States
(12) Patent Application Publication
(10) Pub. No.: US 2010/0188126 A1
(43) Pub. Date: Jul. 29, 2010

(54) Voltage Controlled Duty Cycle and Non-Overlapping Clock Generation Implementation

(75) Inventors: Sharon W. Cheung, San Jose, CA (US); Chad B. McBride, Rochester, MN (US); Cheng-Fu Frank Tsai, San Jose, CA (US); Jianguo Yao, Fremont, CA (US)

Correspondence Address: IBM CORPORATION, 3605 HIGHWAY 52 NORTH, DEPT 917, ROCHESTER, MN, 55901-7829, US

(73) Assignee: INTERNATIONAL BUSINESS MACHINES CORPORATION, Armonk, NY (US)

(21) Appl. No.: 12/359,583

(22) Filed: Jan. 26, 2009

(51) Int. Cl. H03K 3/017

(52) U.S. Cl. 327/175

(57) ABSTRACT

A method, system and apparatus for controlling the duty cycle of a clock to optimize duty cycle correction and non over-lapping clock generation. The first system generates a reference voltage and one or more clock signals. A comparison is made between the DC level of an output clock and the reference voltage. A correct duty cycle of the clock signal is equal to a predetermined ratio of high time to low time, within an acceptable margin, wherein the ratio of high time to low time is derived from a first resistor and a second resistor. A second system is developed to generate non-overlap clock signals with non-overlap gap control, wherein a reference voltage of a first circuit network is the reference voltage of a second circuit network; thereby generating a single reference signal for the non-overlap circuit network.

### BACKGROUND

1. Technical Field

The present invention generally relates to logic circuits and in particular to duty cycle correction in logic circuits.

2. Description of the Related Art

Applications, such as double data rate (DDR) and quad data rate (QDR), utilize duty cycle correction. Duty cycle correction is utilized to adjust the duty cycle of a clock to 50% when an application utilizes both rising and falling clock edges for data propagation. DDR and QDR applications rely on the idea that data transitions proportionally between two half cycles of the clock. An unbalanced duty cycle reduces the signal propagation time and adversely affects the performance of the circuitry. The correction capability of the duty cycle control circuit is a key issue for high-speed data applications (e.g. DDR, QDR).

Digital circuits require a clock signal to operate. Typically, the clock signal is provided by a crystal oscillator and associated circuitry, which usually does not provide a clock signal having a duty cycle of 50%. For example, the clock signal may have a duty cycle of 45%, wherein the logic high time of the clock signal is 45% of the clock cycle, and the logic low time of the clock signal is the remaining 55% of the clock cycle. In many applications, a desire is to have the duty cycle of the clock signal be maintained at 50%. However, most clock generation circuits and clock signal amplifier and buffer circuits introduce some level of error from the desired 50% duty cycle.

### SUMMARY OF ILLUSTRATIVE EMBODIMENTS

Disclosed are a method, system and apparatus for controlling the duty cycle of a clock to optimize duty cycle correction and non over-lapping clock generation. The first system generates a reference voltage and one or more clock signals. When the one or more clock signals are generated, the clock signals are input into a comparator and a filter. A comparison is made between the DC level of the output clock and the reference voltage. After extracting the duty cycle information, which is the direct current (DC) level of the clock out signal, the correct duty cycle of the clock signal is equal to a predetermined ratio of high time to low time, within an acceptable margin, wherein the predetermined ratio of high time to low time is derived from a first resistor and a second resistor. The duty cycle control circuit detects and corrects the duty cycle, as provided by the control voltage, to equal the predetermined ratio of high time to low time within the acceptable margin. A second system is also developed to generate non-overlap clock signals with non-overlap gap control. A non-overlap clock signal is generated when a first circuit network receives a first input clock signal and a second circuit network receives a second input clock signal, in which the second input clock is complementary to the first input clock. The reference voltage of the first circuit network is the reference voltage of the second circuit network; thereby generating a single reference signal for the non-overlap circuit network.

The above as well as additional features of the present invention will become apparent in the following detailed written description.

### BRIEF DESCRIPTION OF THE DRAWINGS

The invention itself will best be understood by reference to the following detailed description of an illustrative embodiment when read in conjunction with the accompanying drawings, wherein:

FIG. 1 is a block diagram of a duty cycle control circuit according to one embodiment of the invention;

FIG. 2 is a circuit diagram of a duty cycle control circuit in accordance with one embodiment of the invention;

FIG. 3 is a circuit diagram of a comparator and filter circuit in accordance with one embodiment of the invention;

FIG. 4 is a diagram of a duty cycle control circuit network in accordance with one embodiment of the invention;

FIG. 5A is a circuit diagram of a non-overlap clock generation circuit network in accordance with one embodiment of the invention;

FIG. 5B is a graphical comparison of clock signals in accordance with one embodiment of the invention; and

FIG. 6 is a logic flow chart of the process for correcting the duty cycle according to one embodiment of the invention.

### DETAILED DESCRIPTION OF AN ILLUSTRATIVE EMBODIMENT

The illustrative embodiments provide a method, system and apparatus for controlling the duty cycle of a clock to optimize duty cycle correction and non over-lapping clock generation. The first system generates a reference voltage and one or more clock signals. When the one or more clock signals are generated, the clock signals are input into a comparator and a filter. A comparison is made between the DC level of the output clock and the reference voltage. After extracting the duty cycle information, which is the direct current (DC) level of the clock out signal, the correct duty cycle of the clock signal is equal to a predetermined ratio of high time to low time, within an acceptable margin, wherein the predetermined ratio of high time to low time is derived from a first resistor and a second resistor. The duty cycle control circuit detects and corrects the duty cycle, as provided by the control voltage, to equal the predetermined ratio of high time to low time within the acceptable margin. A second system is also developed to generate non-overlap clock signals with non-overlap gap control. A non-overlap clock signal is generated when a first circuit network receives a first input clock signal and a second circuit network receives a second input clock signal, in which the second input clock is complementary to the first input clock. The reference voltage of the first circuit network is the reference voltage of the second circuit network; thereby generating a single reference signal for the non-overlap circuit network.

In the following detailed description of exemplary embodiments of the invention, specific exemplary embodiments in which the invention may be practiced are described in sufficient detail to enable those skilled in the art to practice the invention, and it is to be understood that other embodiments may be utilized and that logical, architectural, programmatic, mechanical, electrical and other changes may be made without departing from the spirit or scope of the present invention. The following detailed description is, therefore, not to be taken in a limiting sense, and the scope of the present invention is defined only by the appended claims.

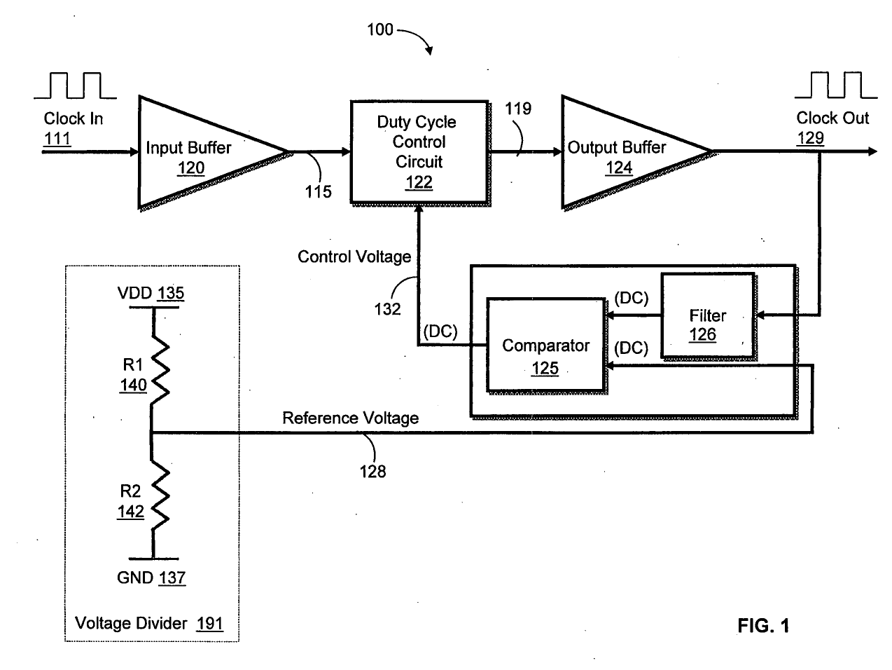

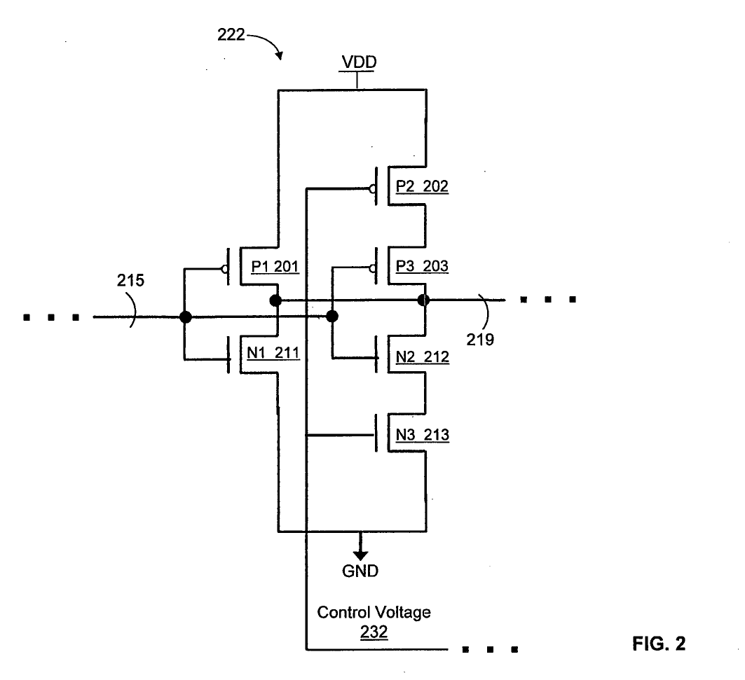

Within the descriptions of the figures, similar elements are provided similar names and reference numerals as those of the previous figure(s). Where a later figure utilizes the element in a different context or with different functionality, the element is provided a different leading numeral representative of the figure number (e.g., 1xx for FIG. 1 and 2xx for FIG. 2). The specific numerals assigned to the elements are provided solely to aid in the description and not meant to imply any limitations (structural or functional) on the invention.

It is understood that the use of specific component, device and/or parameter names are for example only and not meant to imply any limitations on the invention. The invention may thus be implemented with different nomenclature/terminology utilized to describe the components/devices/parameters herein, without limitation. Each term utilized herein is to be given its broadest interpretation given the context in which that terms is utilized. Specifically, as utilized herein, the term “equal” in relation to duty cycle and duty cycle values, refer to a value that is approximately or close to the said value of interest. The term “approximately equal to 50%/50%” is described as the predetermined ratio of high time to low time.

With reference now to the figures, FIG. 1 depicts a block diagram representation of a duty cycle control circuit, voltage control duty cycle circuit (VCDC) 100. VCDC 100 includes multiple apparatus and associated signals. VCDC comprises input buffer 120, duty cycle circuit 122, output buffer 124, as well as comparator and filter circuit 126. Input buffer 120 receives clock in signal 111. Input buffer 120 outputs buffered signal 115 to duty cycle control circuit 122. Duty cycle control circuit outputs duty cycle 119 to output buffer 124. Output buffer 124 outputs clock out signal 129. Filter circuit 126 receives clock out signal 129. Comparator circuit 125 receives the output of filter circuit 126 and reference voltage 128. Comparator circuit 125 outputs comparator voltage 132 to duty cycle control circuit 122. Within voltage divider 191 are resistor 1 140 and resistor 2 142. Resistor 1 140 and resistor 2 142 are a first resistor and a second resistor connected in series, and allow reference voltage 128 to be delivered via voltage drain drain (VDD) 135 and ground (GND) 137. When R1 (140) and R2 (142) are equal, a theoretical 50%/50% duty cycle value is achieved. A predetermined ratio of high time to low time is derived from R1 (140) and R2 (140) (within an acceptable margin).

Among the apparatus provided by VCDC 100, and which are specific to the invention, are: (a) means for inputting a clock signal into a comparator and a filter, wherein the comparator and the filter output one or more signals to a duty cycle control circuit; (b) means for detecting whether the DC level of the output clock is equal to the reference voltage, wherein the reference voltage is equal to a predetermined ratio of high time to low time; and (c) means for correcting a duty cycle to equal a predetermined ratio of high time to low time, when the predetermined ratio is derived from one or more resistors.

VCDC 100 initiates a series of functional processes that enable the above functional features as well as additional features/functionality, which are described below within the description of FIGS. 2-6.

With reference now to FIG. 2, wherein is depicted a circuit for correcting a duty cycle. Duty cycle control (DCC) circuit 222 comprises the following positive channel (p-channel) transistors: P1 201 (first transistor), P2 202, and P3 203. DCC circuit 222 also includes the following negative channel (N-channel) transistors: N1 211 (second transistor), N2 212, and N3 213. Buffered signal 215 and control voltage 232 are received by DCC circuit 222. Duty cycle control circuit output 219 is output by DCC circuit 222.

In one embodiment, DCC circuit 222 is a circuitry for correcting a duty cycle to equal one half of a reference voltage. The drain of N1 211 is connected to the drain of P1 201. The gates of P1 201 and N1 211 are connected. The gates of P1 201 and N1 211 are connected to the gates of P3 203 and N2 212. P3 203 and N2 212 are connected via the gates of each transistor. The drain of P3 203 is connected to the drain of N2 212, while the source of N2 212 connects to the drain of N3 213. The source of N3 213 connect to the source of N1 211 and the gate of N3 213 connect to the gate of P2 202. The drain of P2 202 connects to the source of P3 203. DCC circuit 222 form a circuit network in which P2 202, P3 203, N2 212, and N3 213 are each connected in series, respectively. The series connection of P2 202, P3 203, N2 212, and N3 213 are connected parallel to the series connection of P1 201 and N1 211.

In one embodiment, DCC circuit 222 outputs a corrected duty cycle control circuit output. Buffered signal 215 is received by the gates of P1 201 and N1 211. Buffered signal 215 is also transmitted to the gates of P3 203 and N2 212. The gates of P2 202 and N3 213 receive control voltage 232. The input signals of buffered signal 215 and control voltage 232 propagate through DCC circuit 222, resulting in an output signal, or duty cycle control circuit output 219. The duty cycle information is retrieved from the direct current (DC) level of the clock signal. After extracting the duty cycle information (duty cycle control circuit output 219), the corrected duty cycle of the clock signal is equal to fifty percent. DCC circuit 222 corrects the DC signal to equal the reference voltage, when the reference voltage is fifty percent of VDD.

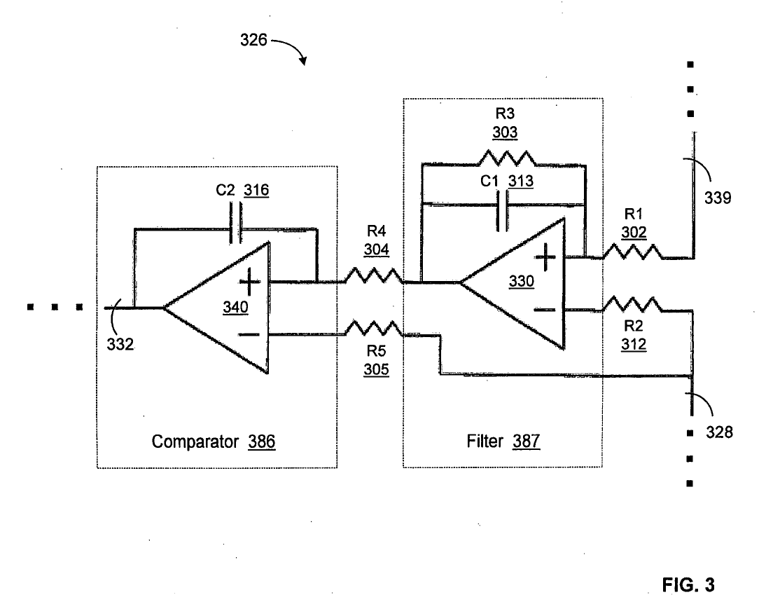

FIG. 3 illustrates a circuitry for comparing one or more input signals. Comparator and filter circuit 326 includes comparator circuit 386 and filter circuit 387. Comparator and filter circuit 326 comprises operational amplifier (op-amp) 1 330 ( of filter circuit 387), op-amp 2 340 (of comparator circuit 386), capacitor 1 (C1) 313, capacitor 2 (C2) 316, and the following resistors: R1 302, R2 312, R3 303, R4 304, and R5 305. One or more inputs are received by comparator and filter circuit 326, DC level of output clock 339 and reference voltage 328. Comparator and filter circuit 326 also produces an output, control voltage 332.

In one embodiment, a circuit network is configured to receive one or more input signals and produce an output based on the comparison of the input signals. R1 302 is connected to the non-inverting input of op-amp 1 330, and R2 312 is connected to the inverting input of op-amp 330. R4 304 is connected to the output of op-amp 1 330. R3 303 is connected in parallel with C1 313. The parallel pair of C1 313 and R3 303 is connected to R1 302 and R4 304. R4 304 is coupled to the non-inverting input of op-amp 2 340, and R5 305 is coupled to the inverting input of op-amp 2 340. C2 316 connects to R4 304 as well as the output of op-amp 2 340. In one embodiment the comparator and filter circuit continuously outputs a control voltage. Current may flow through an open collector of the one or more op-amps (op-amp 1 330 and op-amp 2 340), within comparator and filter circuit 326, when DC level of clock out 339 is lower than reference voltage 332. When DC level of clock out 339 is lower than reference voltage 328, control voltage 332 is transmitted to DCC circuit 222 (of FIG. 2). When control voltage 332 is transmitted to DCC circuit 222, DCC circuit 222 corrects the duty cycle by controlling the trip point of the clock signals.

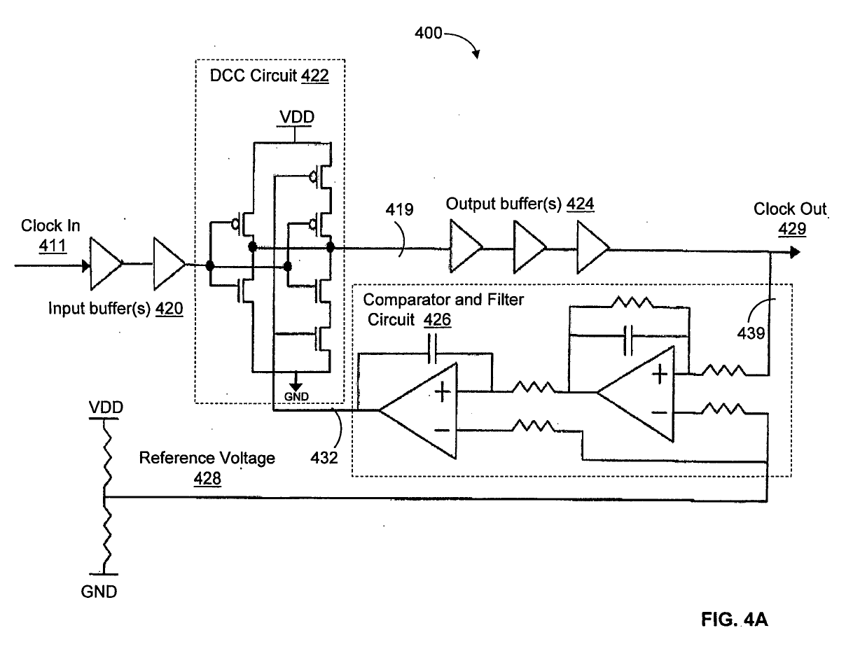

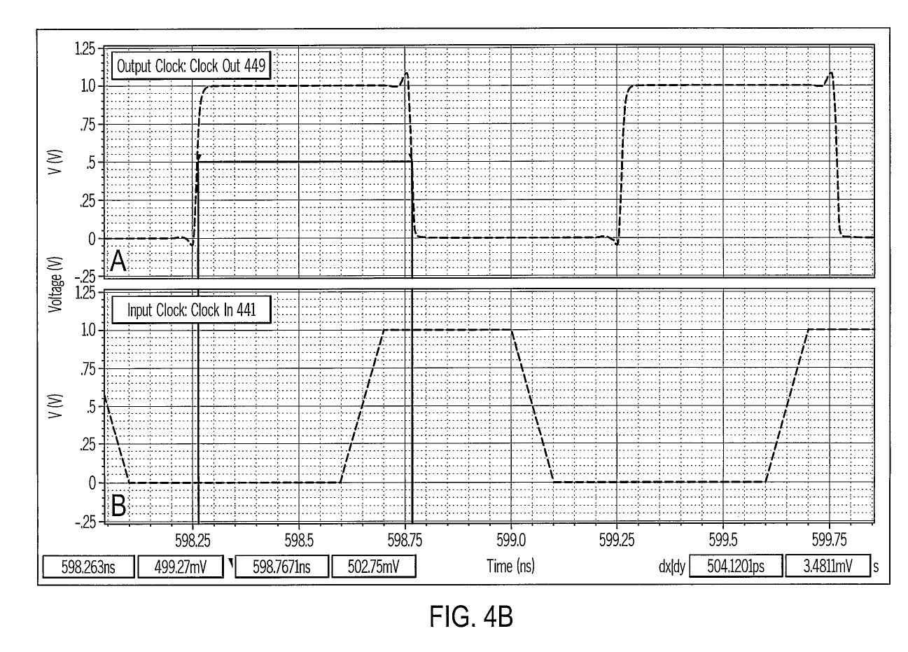

FIG. 4A illustrates a circuit network for correcting duty cycle. Circuit network 400 of FIG. 4A comprises input buffer(s) 420, duty cycle control (DCC) circuit 422, output buffer(s) 424, as well as comparator and filter circuit 426. Input buffer(s) 420 receive clock in signal 411. DCC circuit 422 outputs duty cycle control circuit output 419. Duty cycle control circuit output 419 is received by output buffer(s) 424 from DCC circuit 422. Output buffer(s) 424 outputs clock out signal 429. Comparator and filter circuit 426 receives two signals, DC level of clock out 439 and reference voltage 428. Comparator and filter circuit 426 outputs control voltage 432 to DCC circuit 422.

In one embodiment, circuit network 400 provides means for extracting a control voltage signal when the filter receives one or more of: a clock out signal and reference voltage. Input buffer(s) 420 receive a first clock signal, clock in signal 411. When clock in signal 411 is transmitted through DCC circuit 422, the resulting signal is duty cycle control circuit output 419. Output buffer(s) 424 receive duty cycle control circuit output 419. Clock out signal 429, of the second clock, may be detected (via an off circuit signal detector) and, and the DC signal of the second clock is received by comparator and filter circuit 426 as DC level of clock out 439. A first op-amp (op-amp 1 330, of FIG. 3) receives clock out signal 429 and reference voltage 428. Clock out signal 429 and reference voltage 428 are detected at the second op-amp (op-amp 2 340, of FIG. 3). When DC level of clock out 439 is compared to reference voltage 428, circuit network 400 provides means for outputting control voltage 432. Comparator and filter circuit 426 outputs control voltage 432, from a second op-amp (op-amp 2 340, of FIG.3), and control voltage 432 is received by DCC circuit 422.

In another embodiment, circuit network 400 provides means for detecting whether the DC level of the output clock is equal to the reference voltage. Circuit network 400 of FIG.4A operates according to a clock. The direct current (DC) level, provided by clock out signal 429, corresponds to the duty cycle information of the clock. The DC level (DC component) of clock out signal 429 is extracted by the filter (low-pass filter) of comparator and filter circuit 426. The DC level of the clock (or DC level of clock out 439) is compared to reference voltage 428, wherein the value of reference voltage 428 is the target of DC level of clock out 439. Control voltage 432 is input into DCC circuit 422, if the duty cycle is not equal to the predetermined ratio of high time to low time; the duty cycle is automatically corrected via DCC circuit 422. DCC circuit 422 corrects the duty cycle by controlling the trip point of the clock signals. The direct current (DC) level of the clock out signal is automatically corrected to equal the reference voltage when the control voltage is detected at DCC circuit 422.

FIG. 4B graphically represents results for duty cycle control. Clock out signal 449 and clock in signal 441 represent clock out signal 429 and clock in signal 411 in frames A and B, respectively. The waveform of FIG. 4B illustrates the duty cycle may be corrected when circuit network 400 is utilized. For example, when the duty cycle of clock in 411 is set to 60%/40% with a reference voltage equal to half VDD, the output clock is 50.4%. The duty cycle is corrected from 60%/40% to 50.4%/49.6%. The corrected percentage is 9.6%, as depicted by FIG. 4B.

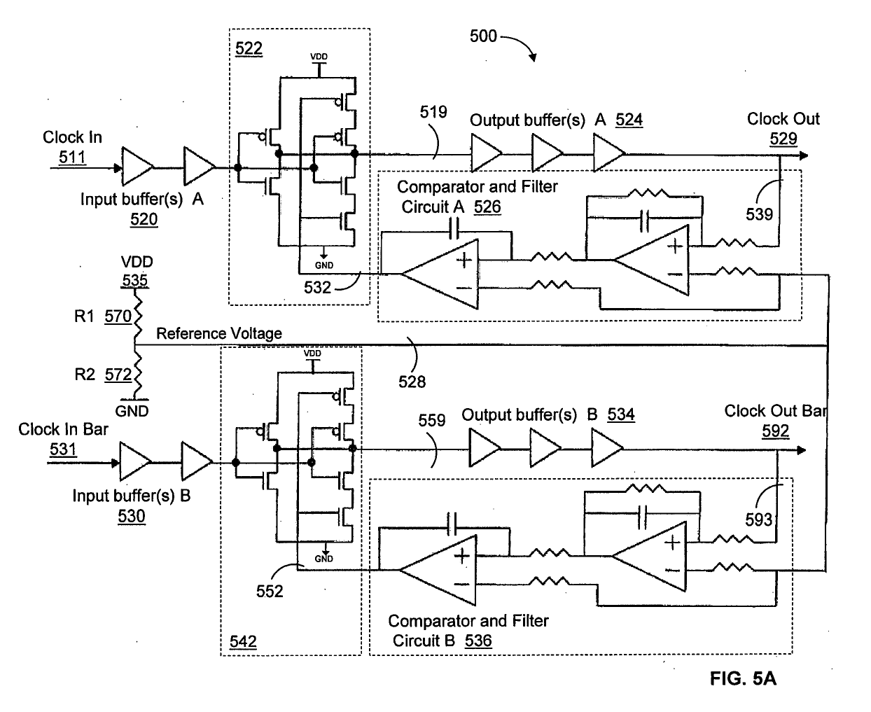

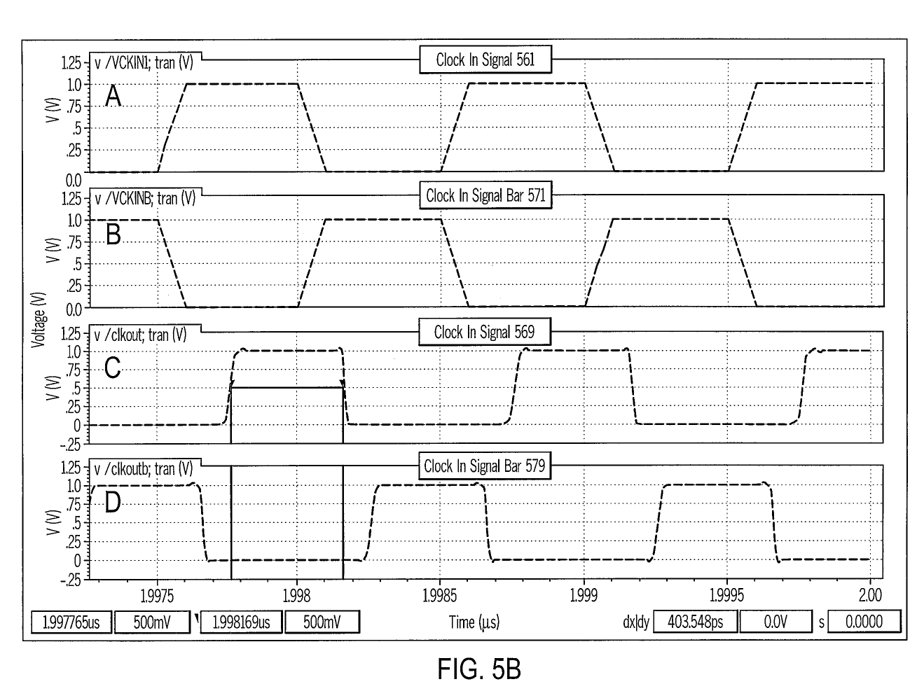

FIG. 5A illustrates a circuit network for controlling non-overlap clock generation, wherein a first circuit network and a second circuit network are utilized to control the non-overlap clock generation. The first circuit network of non-overlap circuit network 500 comprises: input buffer(s) A 520, DCC circuit A 522, output buffer(s) A 524, as well as comparator and filter circuit A 526. Input buffer(s) A 520 receive clock in signal 511. DCC circuit A 522 outputs duty cycle control circuit output A 519. Duty cycle control circuit output A 519 is received by output buffer(s) A 524 from DCC circuit A 522. Output buffer(s) A 524 outputs clock out signal 529. Comparator and filter circuit A 526 receive a first clock signal, DC level of clock out 539. Reference voltage 528 is also received by a filter (e.g. filter circuit 387 of FIG. 3) and a comparator (e.g. comparator circuit 386 of FIG. 3) of comparator and filter circuit A 526. Comparator and filter circuit A 526 outputs control voltage A 532 to DCC circuit A 522. VDD 535 contributes to the delivery of reference voltage 528. VDD is delivered by a resistor 1 (R1) 570 in series with resistor 2 (R2) 572. The reference voltage is dependent on the duty cycle desired, wherein the theoretical duty cycle percentage is equivalent to a second resistor divided by a the sum of a first and second resistor (R2/(R1+R2)).

The second circuit network of non-overlap circuit network 500 comprises: input buffer(s) B 530, DCC circuit B 542, output buffer(s) B 534, as well as comparator and filter circuit B 536. Input buffer(s) B 530 receive a second clock signal, clock in bar signal 531, wherein clock in bar signal 531 is a differential signal. DCC circuit B 542 transmits output of DCC circuit B 559. Output of DCC circuit B 559 is received by output buffer(s) B 534 from DCC circuit B 542. Output buffer(s) B 534 outputs clock out bar signal 592, wherein clock out bar signal 592 is a differential signal. Comparator and filter circuit B 536 receives two signals, DC level of clock out bar 593 and reference voltage 528. A filter circuit and a comparator circuit, of comparator filter circuit B 536 receive reference voltage 528. Comparator and filter circuit B 536 outputs control voltage B 552 to DCC circuit B 542.

In one embodiment, non-overlap circuit network provides means for controlling non-overlap clock signals when the duty cycle of the clock output is controlled by the reference voltage. For example, the duty cycle of clock in signal 511 and clock in bar signal 531 are equivalent to fifty percent of a given signal (duty cycle overlap clock signal), and reference voltage 528 is equal to forty percent of VDD 535. When the values of the duty cycle of clock in signal 511, clock in bar signal 531, and reference voltage 528 are provided to non-overlap circuit network 500, the high time of clock out signal 529 overlaps and is centered to the low time of clock out bar signal 592. The results are depicted in FIG. 5B.

FIG. 5B graphically represents results for non-overlap clock generation. Clock in signal 511 and clock in signal bar 531 are represented by clock in signal 561 and clock in signal bar 571, respectively, in frames A and B of FIG. 5B. Clock out signal 529 and clock out signal bar 593 are represented by clock out signal 569 and clock out signal bar 579, respectively, in frames C and D of FIG. 5B. According to the example provided in the description of FIG. 5A, setting the values of the clock in signals and reference voltage allow clock out signal 529 and clock out signal bar 593 to equal 40.3% (logic 1)/59.7% (logic 0). Transmitting the signals through non-overlap circuit network 500 results in a non-overlap time of 19.4%.

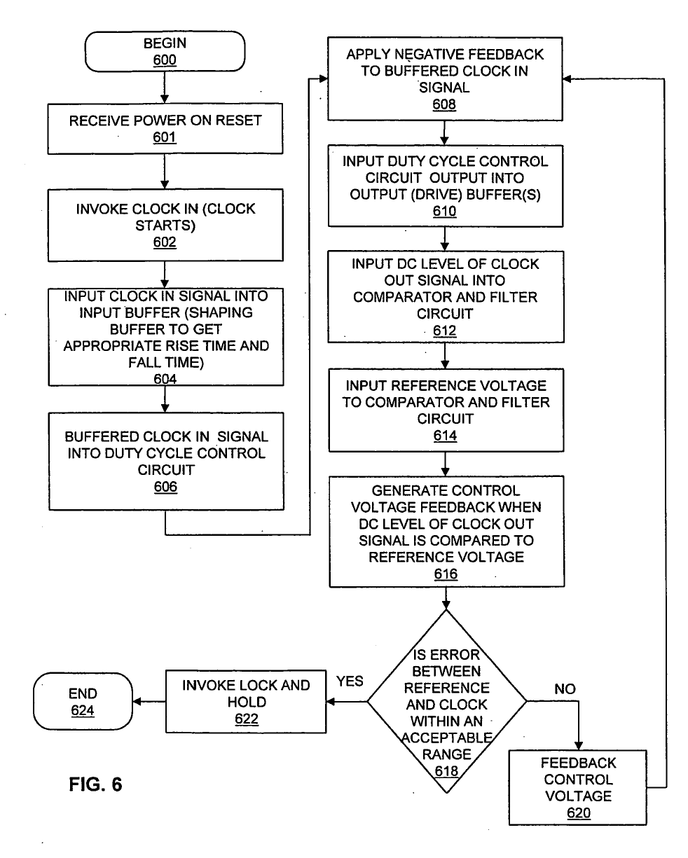

FIG. 6 is a flow chart illustrating various methods by which the above processes of the illustrative embodiments are completed. Although the methods illustrated in FIG. 6 may be described with reference to components shown in FIGS. 1-5, it should be understood that this is merely for convenience and alternative components and/or configurations thereof can be employed when implementing the various methods. Key portions of the methods may be completed utilizing circuit network 400 and/or non-overlap circuit network 500, and controlling specific operations of DCC circuit 222 and comparator and filter circuit 326. The methods are thus described from the perspective of either circuit network 400 or non-overlap circuit network 500.

FIG. 6 depicts a process for correcting the duty cycle. The process of FIG. 6 begins at initiator block 600 and proceeds to block 601. At block 601 power is received by the reset component. When power is received by the reset component, clock in is invoked (i.e. clock in starts), at block 602. At block 604 clock in signal is input into the input buffer. The input buffer enables the clock in signal to obtain the appropriate rise time and fall time. The buffered clock in signal is input into the duty cycle control circuit at block 606. At block 608, negative feedback is applied to the buffered clock in signal. The output signal of the duty cycle control circuit is input into the output buffers, at block 610, wherein the output buffers produce an output clock signal.

At block 612 the DC level of the clock out signal is input into the filter of the comparator and filter circuit. A reference voltage is generated by the circuit network and the reference voltage is input into the comparator of the comparator and filter circuit at block 614. Control voltage feedback is generated, at block 616, when the DC level of the clock out signal is compared to the reference voltage. A decision is made, at block 618, whether the comparison between the reference voltage signal and the DC level of the clock out signal provide an acceptable margin of error. If the comparison between the reference voltage signal and the DC level of the clock signal do not provide an acceptable range of error, a control voltage is fed back to the duty cycle control circuit at block 618. When the control voltage is fed back into the duty cycle control circuit, the process continues to block 608. If the comparison between the reference voltage signal and the DC level of the clock in signal provide an acceptable range of error, lock and hold is invoked at block 622. The process ends at block 624.

In some implementations, certain steps of the methods are combined, performed simultaneously or in a different order, or perhaps omitted, without deviating from the spirit and scope of the invention. Thus, while the method steps are described and illustrated in a particular sequence, use of a specific sequence of steps is not meant to imply any limitations on the invention. Changes may be made with regards to the sequence of steps without departing from the spirit or scope of the present invention. Use of a particular sequence is therefore, not to be taken in a limiting sense, and the scope of the present invention is defined only by the appended claims.

While the invention has been described with reference to exemplary embodiments, it will be understood by those skilled in the art that various changes may be made and equivalents may be substituted for elements thereof without departing from the scope of the invention. In addition, many modifications may be made to adapt a particular system, device or component thereof to the teachings of the invention without departing from the essential scope thereof. Therefore, it is intended that the invention not be limited to the particular embodiments disclosed for carrying out this invention, but that the invention will include all embodiments falling within the scope of the appended claims. Moreover, the use of the terms first, second, etc. do not denote any order or importance, but rather the terms first, second, etc. are used to distinguish one element from another.

What is claimed is:

1. A method for controlling the duty cycle of a clock, the method comprising:
generating a reference voltage;
generating one or more signals from a first clock and a second clock;
inputting a first clock signal into the gates of a first transistor and a second transistor of a duty cycle control circuit, wherein the duty cycle control circuit includes a series connection of the first positive type (p-type) and the first negative (n-type) transistor connected in parallel to one or more p-type transistors in series with one or more n-type transistors;
inputting a second clock signal into a comparator and filter circuit;
detecting an output signal of a filter at a comparator, when the output signal of the filter is connected to the input of the comparator;
receiving an output signal of the comparator at the duty cycle control circuit, wherein the output signal of the comparator is a control voltage;
extracting a direct current (DC) signal of the second clock from the filter;
when the second clock signal and reference voltage is received at the filter, transmitting the second clock signal to the comparator;
detecting the DC level of a filtered second clock and the reference voltage at the comparator;
comparing the DC level of the filtered second clock to the reference voltage;
when the DC level of the filtered second clock is compared to the reference voltage, outputting a control voltage to the duty cycle control circuit;
detecting the control voltage at the duty cycle control circuit;
detecting when a duty cycle is approximately equal to a predetermined ratio of high time to low within a tolerance range, wherein the predetermined ratio of high time to low time is derived by the voltage divider;
when the control voltage is detected at the duty cycle control circuit, correcting the duty cycle of the first clock signal;
controlling non-overlap clock signals when the duty cycle is dependent on the reference voltage; and
generating non-overlap clock signals when a first duty cycle control circuit receives a first input clock signal and a second duty cycle control circuit receives a second input clock signal.
